(19) United States
(12) Patent Application Publication
(10) Pub. No.: US 2026/0110717 A1
(43) Pub. Date: Apr. 23, 2026

(54) METHODS AND APPARATUS FOR HEAT EXTRACTION IN A METER COLLAR

(71) Applicant: Enphase Energy, Inc., Petaluma, CA (US)

(72) Inventors: Jarrett Duvall GOODELL, Austin, TX (US); Blake Richard LUNDSTROM, Lakewood, CO (US); Jingyuan YAN, Cedar Park, TX (US)

(21) Appl. No.: 19/358,710

(22) Filed: Oct. 15, 2025

Related U.S. Application Data
(60) Provisional application No. 63/710,771, filed on Oct. 23, 2024.

(51) Int. Cl. G01R 22/06

(52) U.S. Cl. CPC G01R 22/065

(57) ABSTRACT

A meter collar configured to connect to a utility meter is provided herein and comprises a live part that generates heat and is coated with a first material providing electrical isolation between a heat sink and the live part, wherein the heat sink connects to the first material via a second material that does not compress the first material so that a predetermined distance, which allows the heat sink to perform conduction heat transfer from the live part during operation of the utility meter, is maintained between the live part and the heat sink.

### CROSS-REFERENCE TO RELATED APPLICATIONS

The present application claims the benefit of and priority to U.S. Provisional Application Ser. No. 63/710,771, filed on Oct. 23, 2024, the entire contents of which is incorporated herein by reference.

### BACKGROUND

### 1. Field of the Disclosure

Embodiments of the present disclosure generally relate to meter collars and, for example, to methods and apparatus for heat extraction in a meter collar.

### 2. Description of the Related Art

Conventional power conversion systems are known and can comprise a load center that is coupled to a meter (utility) that can couple to a MID (microgrid interconnect device) that can be connected to a grid (e.g., a commercial/utility power grid). In some instances, a meter collar can interface electrically and mechanically with a meter socket of the meter and is required to pass stringent thermal requirements, essentially not allowing the meter collar to heat the meter socket more than normal operation without the meter collar.

Busbars and relays are integral components of the meter collar and can be a large source of unwanted heat generation. Fans or other active devices can be used to minimize the unwanted heat generation, but using such devices can be costly. Additionally, there are strict requirements on clearance (e.g., about 9.5 mm) between live parts, such as bus bars, grounded heat sink parts, etc., but there are certain exceptions for certain types of material barriers if the material barriers are not compressed.

Therefore, described herein are improved methods and apparatus for heat extraction in a meter collar.

### SUMMARY

In accordance with some aspects of the present disclosure, a meter collar configured to connect to a utility meter comprises a live part that generates heat and is coated with a first material providing electrical isolation between a heat sink and the live part, wherein the heat sink connects to the first material via a second material that does not compress the first material so that a predetermined distance, which allows the heat sink to perform conduction heat transfer from the live part during operation of the utility meter, is maintained between the live part and the heat sink.

In accordance with some aspects of the present disclosure, an energy management system comprises a load center configured to connect to a distributed energy resource, a utility meter coupled to the load center, and a meter collar comprising a live part that generates heat and is coated with a first material providing electrical isolation between a heat sink and the live part, wherein the heat sink connects to the first material via a second material that does not compress the first material so that a predetermined distance, which allows the heat sink to perform conduction heat transfer from the live part during operation of the utility meter, is maintained between the live part and the heat sink.

In accordance with some aspects of the present disclosure, a method of manufacturing a meter collar configured to connect to a utility meter comprises coating a live part that generates heat with a first material providing electrical isolation between a heat sink and the live part and connecting the heat sink to the first material via a second material that does not compress the first material so that a predetermined distance, which allows the heat sink to perform conduction heat transfer from the live part during operation of the utility meter, is maintained between the live part and the heat sink.

Various advantages, aspects, and novel features of the present disclosure may be appreciated from a review of the following detailed description of the present disclosure, along with the accompanying figures in which like reference numerals refer to like parts throughout.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only a typical embodiment of this disclosure and are therefore not to be considered limiting of its scope, for the disclosure may admit to other equally effective embodiments.

FIG. 1 is a block diagram of a system for power conversion, in accordance with at least some embodiments of the present disclosure;

FIG. 2 is a diagram of a meter collar configured for use with the system for power conversion of FIG. 1, in accordance with at least some embodiments of the present disclosure;

FIG. 3 is a block diagram of a meter collar of FIG. 2, in accordance with at least some embodiments of the present disclosure; and

FIG. 4 is a method of manufacturing a meter collar configured to connect to a utility meter, in accordance with at least some embodiments of the present disclosure.

### DETAILED DESCRIPTION

In accordance with the present disclosure, described herein are improved methods and apparatus for heat extraction in a meter collar. For example, a meter collar configured to connect to a utility meter can comprise a live part that generates heat and is coated with a first material providing electrical isolation between a heat sink and the live part. The heat sink can connect to the first material via a second material that does not compress the first material so that a predetermined distance, which allows the heat sink to perform conduction heat transfer from the live part during operation of the utility meter, is maintained between the live part and the heat sink. The methods and apparatus described herein minimize unwanted heat generation without using fans. Additionally, since the first material is not compressed during manufacture, a predetermined distance (e.g., about 9.5 mm) is maintained between the live part and the heat sink, which allows the heat sink to perform conduction heat transfer from the live part during operation of the utility meter.

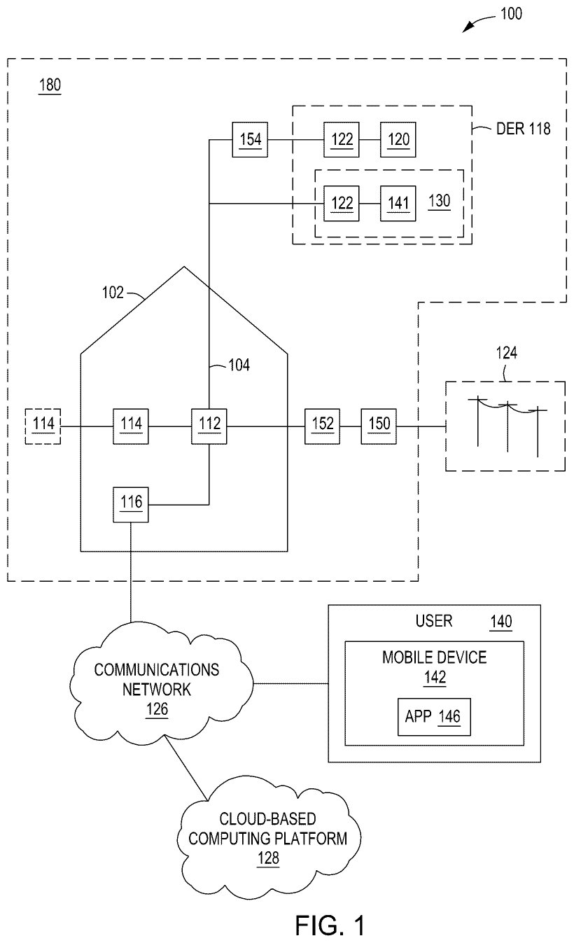

FIG. 1 is a block diagram of an energy management system (e.g., power conversion system, system 100) in accordance with one or more embodiments of the present disclosure. The diagram of FIG. 1 only portrays one variation of the myriad of possible system configurations. The present disclosure can function in a variety of environments and systems.

The system 100 comprises a structure 102 (e.g., a user's structure), such as a residential home, commercial building, or separate mounting structure, having an associated DER 118 (distributed energy resource). The DER 118 is situated external to the structure 102. For example, the DER 118 may be located on the roof of the structure 102 or can be part of a solar farm. Alternatively, the DER 118 can be situated internal to the structure 102. For example, when the DER 118 is a permanent residential battery energy storage system, the DER 118 may be installed in a garage (or other suitable location inside the structure 102). The structure 102 comprises one or more loads and/or energy storage devices 114 (e.g., portable energy systems (PES), appliances, electric hot water heaters, thermostats/detectors, boilers, electric vehicle supply equipment (EVSE), EVs, water pumps, and the like), which can be located within or outside the structure 102, and a DER controller 116, each coupled to a load center 112. Although the energy storage devices 114, the DER controller 116, and the load center 112 are depicted as being located within the structure 102, one or more of these may be located external to the structure 102.

The load center 112 is coupled to the DER 118 by an AC bus 104 and is further coupled, via a meter 152 (utility meter comprising a utility meter socket) and optionally a MID 150 (microgrid interconnect device), to a grid 124 (e.g., a commercial/utility power grid). The structure 102, the energy storage devices 114, DER controller 116, DER 118, load center 112, generation meter 154, the meter 152, and the MID 150 are part of a microgrid 180. It should be noted that one or more additional devices not shown in FIG. 1 may be part of the microgrid 180. For example, a power meter or similar device may be coupled to the load center 112.

The DER 118 comprises at least one renewable energy source (RES) coupled to power conditioners 122 (e.g., microinverter, power converter, power conversion units (PCUs), etc.). For example, the DER 118 may comprise a plurality of RESs 120 coupled to a plurality of power conditioners 122 in a one-to-one correspondence (or two-to-one). In embodiments described herein, each RES of the plurality of RESs 120 is a photovoltaic module (PV module), although in other embodiments the plurality of RESs 120 may be any type of system for generating DC power from a renewable form of energy, such as wind, hydro, and the like. The DER 118 may further comprise one or more batteries (or other types of energy storage/delivery devices) coupled to the power conditioners 122 in a one-to-one correspondence, where each pair of power conditioner 122 and a DC battery 141 may be referred to as an AC battery 130.

The power conditioners 122 invert the generated DC power from the plurality of RESs 120 and/or the DC battery 141 to AC power that is grid-compliant and couple the generated AC power to the grid 124 via the load center 112. The generated AC power may be additionally or alternatively coupled via the load center 112 to the one or more loads (e.g., EV, EVSE) and/or the energy storage devices 114. In addition, the power conditioners 122 that are coupled to the DC batteries convert AC power from the AC bus 104 to DC power for charging the DC batteries. A generation meter 154 is coupled at the output of the power conditioners 122 that are coupled to the plurality of RESs 120 in order to measure generated power.

In at least some embodiments, the power conditioners 122 may be AC-AC converters that receive AC input and convert one type of AC power to another type of AC power. Alternatively, the power conditioners 122 may be DC-DC converters that convert one type of DC power to another type of DC power. The DC-DC converters may be coupled to a main DC-AC inverter for inverting the generated DC output to an AC output.

The power conditioners 122 may communicate with one another and with the DER controller 116 using power line communication (PLC), although additionally and/or alternatively other types of wired and/or wireless communication may be used. The DER controller 116 may provide operative control of the DER 118 and/or receive data or information from the DER 118. For example, the DER controller 116 may be a gateway that receives data (e.g., alarms, messages, operating data, performance data, and the like) from the power conditioners 122 and communicates the data and/or other information via the communications network 126 to a cloud-based computing platform 128, which can be configured to execute one or more application software, e.g., a grid connectivity control application, to a remote device or system such as a master controller (not shown), and the like. The DER controller 116 may also send control signals to the power conditioners 122, such as control signals generated by the DER controller 116 or received from a remote device or the cloud-based computing platform 128. The DER controller 116 may be communicably coupled to the communications network 126 via wired and/or wireless techniques. For example, the DER controller 116 may be wirelessly coupled to the communications network 126 via a commercially available router. In one or more embodiments, the DER controller 116 comprises an application-specific integrated circuit (ASIC) or microprocessor along with suitable software (e.g., a grid connectivity control application) for performing one or more of the functions described herein (e.g., the methods described herein).

The generation meter 154 (which may also be referred to as a production meter) may be any suitable energy meter that measures the energy generated by the DER 118 (e.g., by the power conditioners 122 coupled to the plurality of RESs 120). The generation meter 154 measures real power flow (kWh) and, in some embodiments, reactive power flow (kVAR). The generation meter 154 may communicate the measured values to the DER controller 116, for example using PLC, other types of wired communications, or wireless communication. Additionally, battery charge/discharge values are received through other networking protocols from the DC battery itself.

The meter 152 may be any suitable energy meter that measures the energy consumed by the microgrid 180, such as a net-metering meter, a bi-directional meter that measures energy imported from the grid 124 and well as energy exported to the grid 124, a dual meter comprising two separate meters for measuring energy ingress and egress, and the like. In some embodiments, the meter 152 comprises the MID 150 or a portion thereof. The meter 152 measures one or more of real power flow (kWh), reactive power flow (kVAR), grid frequency, and grid voltage. The meter 152 measures power flows independently of MID state, i.e., when MID is closed and DER's are connected to the grid and when MID is open and DER's are isolated from the grid.

The MID 150, which may also be referred to as an island interconnect device (IID), connects/disconnects the microgrid 180 to/from the grid 124. The MID 150 comprises a disconnect component (e.g., a, relay, a contactor, or the like) for physically connecting/disconnecting the microgrid 180 to/from the grid 124. For example, the DER controller 116 receives information regarding the present state of the system from the power conditioners 122, and also receives the energy consumption values of the microgrid 180 from the meter 152 (for example via one or more of PLC, other types of wired communication, and wireless communication), and based on the received information (inputs), the DER controller 116 determines when to go on-grid or off-grid and instructs the MID 150 accordingly. In some alternative embodiments, the MID 150 comprises an ASIC or CPU, along with suitable software (e.g., an islanding module) for determining when to disconnect from/connect to the grid 124. For example, the MID 150 may monitor the grid 124 and detect a grid fluctuation, disturbance or outage and, as a result, disconnect the microgrid 180 from the grid 124. Once disconnected from the grid 124, the microgrid 180 can continue to generate power as an intentional island without imposing safety risks, for example on any line workers that may be working on the grid 124.

In some alternative embodiments, the MID 150 or a portion of the MID 150 is part of the DER controller 116. For example, the DER controller 116 may comprise a CPU and an islanding module for monitoring the grid 124, detecting grid failures and disturbances, determining when to disconnect from/connect to the grid 124, and driving a disconnect component accordingly, where the disconnect component may be part of the DER controller 116 or, alternatively, separate from the DER controller 116. In some embodiments, the MID 150 may communicate with the DER controller 116 (e.g., using wired techniques such as power line communications, or using wireless communication) for coordinating connection/disconnection to the grid 124.

A user 140 can use one or more computing devices, such as a mobile device 142 (e.g., a smart phone, tablet, or the like) communicably coupled by wireless means to the communications network 126. The mobile device 142 has a CPU, support circuits, and memory, and has one or more applications (e.g., a grid connectivity control application (an application 146)) installed thereon for controlling the connectivity with the grid 124 as described herein. The mobile device 142 may run on commercially available operating systems, such as IOS, ANDROID, and the like.

In order to control connectivity with the grid 124, the user 140 interacts with an icon displayed on the mobile device 142, for example a grid on-off toggle control or slide, which is referred to herein as a toggle button. The toggle button may be presented on one or more status screens pertaining to the microgrid 180, such as a live status screen (not shown), for various validations, checks and alerts. The first time the user 140 interacts with the toggle button, the user 140 is taken to a consent page, such as a grid connectivity consent page, under setting and will be allowed to interact with toggle button only after he/she gives consent.

Once consent is received, the scenarios below, listed in order of priority, will be managed differently. Based on the desired action as entered by the user 140, the corresponding instructions are communicated to the DER controller 116 via the communications network 126 using any suitable protocol, such as HTTP(S), MQTT(S), WebSockets, and the like. The DER controller 116, which may store the received instructions as needed, instructs the MID 150 to connect to or disconnect from the grid 124 as appropriate.

As noted above, provided herein are improved methods and apparatus for heat extraction in a meter collar. For example, the inventors have found that it is imperative to find passive ways to remove heat from bus bars and/or other heat generating components (e.g., relay terminal) of a meter collar. The inventive concepts described herein balance the above described requirements/desires to permit heat extraction inside of a minimum spacing (e.g., about 9 mm), without compressing one or more barriers that coat the bus bars and/or other heat generating components of the meter collar.

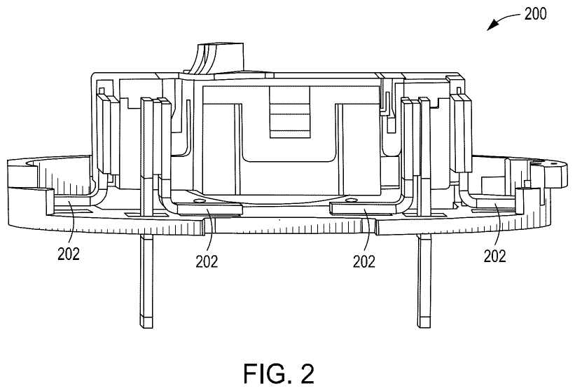

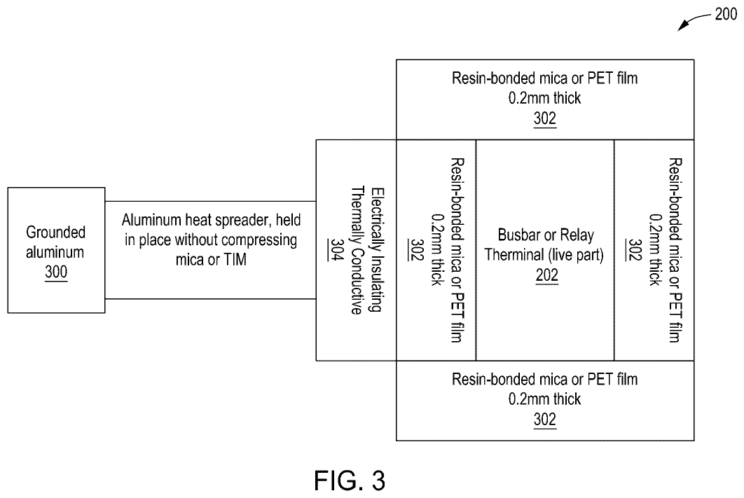

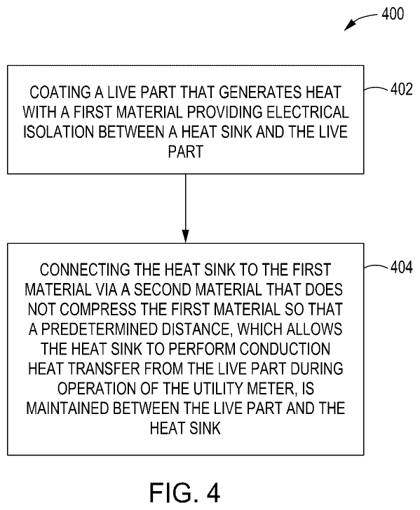

For example, FIG. 2 is a diagram of a meter collar 200 configured for use with the system for power conversion of FIG. 1, FIG. 3 is a block diagram of a meter collar 200 of FIG. 2, and FIG. 4 is a method 400 of manufacturing a meter collar configured to connect to a utility meter (e.g., via a utility meter socket), in accordance with at least some embodiments of the present disclosure.

The meter collar 200 is configured to connect to a utility meter (e.g., the meter 152). The meter collar 200 can comprise one or more live parts 202 that generate heat. For example, the one or more live parts can comprise busbars, relay terminals, or other heat generating devices. During operation, conduction heat transfer from the one or more live parts 202 can be achieved using one or more heat sinks 300 (FIG. 3), e.g., thermally conductive material. For example, the thermally conductive material can be aluminum, copper, or other suitable thermally conductive material. In at least some embodiments, the thermally conductive material can be aluminum. In at least some embodiments, the one or more heat sinks 300 can be maintained at a different voltage level than the one or more live parts 202. In at least some embodiments, the one or more heat sinks 300 can be maintained at about a zero voltage (e.g., typically ground) and the one or more live parts 202 can be maintained greater than about the zero voltage, such as the voltage associated with the busbar, the relay terminal, and/or other heat generating device of the meter collar.

The one or more live parts 202 can be coated with one or more materials 302 (e.g., a first material) providing electrical isolation between the one or more heat sinks 300 and the one or more live parts 202 (see 402 of FIG. 4). For example, the one or more live parts can be coated with at least one of polyethylene terephthalate (PET) film or resin bonded mica. In at least some embodiments, the one or more materials 302 can have a thickness of about 0.2 mm. In doing so, the one or more live parts 202 can be located relatively closer (closer than 9 mm, e.g., a predetermined distance) to the one or more heat sinks 300, which can be a grounded.

The one or more heat sinks 300 connects (see 404 of FIG. 4) to the one or more materials 302 via one or more materials 304 (e.g., a second material, different from the first material) that do not compress the first material so that a predetermined distance (e.g., about 9 mm), which allows the one or more heat sinks 300 to perform conduction heat transfer from the one or more live parts 202 during operation of the meter 152, is maintained between the one or more live parts 202 and the one or more heat sinks 300. In at least some embodiments, the one or more materials 304 can be a gap filler (e.g., gap filler gels that can be two-part dispensed silicone-based materials with glass filler beads), such as the gap fillers manufactured by Bergquist®, Parker Chomerics, Henkel, Laird™, Wakefield Vette, and Dowsil™. In at least some embodiments, the one or more materials 304 can have a thickness of about 0.7 mm.

While the one or more heat sinks have been described herein for use with the one or more live parts of the meter collar, the inventive concepts described herein are not so limited. For example, the one or more heat sinks can be used in conjunction with any of the components, which comprise one or more live parts, of the system 100. Additionally, placement of the one or more materials 302 and/or the one or more materials 304 can be altered as needed. For example, one or more portions of the one or more materials 302 (shown in phantom) of the one or more materials 302 can be omitted. Additionally, the one or more of the portions of one or more materials 302 can have different thicknesses. For example, a portion of the one or more materials 302 adjacent to the one or more materials 304 can have a first thickness (e.g., less than or greater than 0.2 mm) and the one or more of the portions shown in phantom of the one or more materials 302 can have a second thickness (e.g., less than or greater than 0.2 mm), which is different from the first thickness.

While the foregoing is directed to embodiments of the present disclosure, other and further embodiments of the disclosure may be devised without departing from the basic scope thereof, and the scope thereof is determined by the claims that follow.

1. A meter collar configured to connect to a utility meter, comprising:
a live part that generates heat and is coated with a first material providing electrical isolation between a heat sink and the live part, wherein the heat sink connects to the first material via a second material that does not compress the first material so that a predetermined distance, which allows the heat sink to perform conduction heat transfer from the live part during operation of the utility meter, is maintained between the live part and the heat sink.

2. The meter collar of claim 1, wherein the live part is at least one of a busbar or relay terminal of the meter collar.

3. The meter collar of claim 1, wherein the first material is at least one of polyethylene terephthalate (PET) film or resin bonded mica.

4. The meter collar of claim 1, wherein the heat sink is made from at least one of aluminum or copper.

5. The meter collar of claim 1, wherein the heat sink is maintained at a different voltage than the live part.

6. The meter collar of claim 5, wherein the heat sink is maintained at about a zero voltage and the live part is maintained greater than about the zero voltage.

7. The meter collar of claim 1, wherein the predetermined distance is about 9.5 mm.

8. The meter collar of claim 1, wherein the second material is a gap filler gel.

9. The meter collar of claim 1, wherein the meter collar couples to the utility meter via a utility meter socket.

10. An energy management system, comprising:
a load center configured to connect to a distributed energy resource;
a utility meter coupled to the load center; and
a meter collar comprising:
a live part that generates heat and is coated with a first material providing electrical isolation between a heat sink and the live part, wherein the heat sink connects to the first material via a second material that does not compress the first material so that a predetermined distance, which allows the heat sink to perform conduction heat transfer from the live part during operation of the utility meter, is maintained between the live part and the heat sink.

11. The energy management system of claim 10, wherein the live part is at least one of a busbar or relay terminal of the meter collar.

12. The energy management system of claim 10, wherein the first material is at least one of polyethylene terephthalate (PET) film or resin bonded mica.

13. The energy management system of claim 10, wherein the heat sink is made from at least one of aluminum or copper.

14. The energy management system of claim 10, wherein the heat sink is maintained at a different voltage than the live part.

15. The energy management system of claim 14, wherein the heat sink is maintained at about a zero voltage and the live part is maintained at greater than about the zero voltage.

16. The energy management system of claim 10, wherein the predetermined distance is about 9.5 mm.

17. The energy management system of claim 10, wherein the second material is a gap filler gel.

18. The energy management system of claim 10, wherein the meter collar couples to the utility meter via a utility meter socket.

19. A method of manufacturing a meter collar configured to connect to a utility meter, comprising:
coating a live part that generates heat with a first material providing electrical isolation between a heat sink and the live part; and
connecting the heat sink to the first material via a second material that does not compress the first material so that a predetermined distance, which allows the heat sink to perform conduction heat transfer from the live part during operation of the utility meter, is maintained between the live part and the heat sink.

20. The method of claim 19, wherein the live part is at least one of a busbar or relay terminal of the meter collar.
